(19) United States
(12) Patent Application Publication
(10) Pub. No.: US 2026/0262243 A1
(43) Pub. Date: Sep. 3, 2026

(54) SEMICONDUCTOR DEVICE

(71) Applicant: Kabushiki Kaisha Toshiba, Kawasaki-shi (JP)

(72) Inventors: Masahiko KURAGUCHI, Yokohama (JP); Jumpei TAJIMA, Mitaka (JP)

(73) Assignee: Kabushiki Kaisha Toshiba, Kawasaki-shi (JP)

(21) Appl. No.: 19/459,056

(22) Filed: Jan. 26, 2026

(30) Foreign Application Priority Data
Feb. 7, 2025 (JP) 2025-019003

(51) Int. Cl. H10D 30/47; H10D 30/01; H10D 62/10; H10D 62/60; H10D 62/824

(52) U.S. Cl. CPC H10D 30/475; H10D 62/124; H10D 62/60; H10D 62/824; H10D 30/015

(57) ABSTRACT

According to one embodiment, a semiconductor device includes a first electrode, a second electrode, a third electrode, a first semiconductor region, a second semiconductor region, and a third semiconductor region. The first direction is defined as the direction from the first electrode toward the second electrode. The third electrode is provided between the first electrode and the second electrode in the first direction. The first semiconductor region includes Alₓ₁Ga₁₋ₓ₁N (0<x1≤1). The second semiconductor region includes Alₓ₂Ga₁₋ₓ₂N (0≤x2<1, x2<x1). The third semiconductor region includes Alₓ₃Ga₁₋ₓ₃N (0≤x3<1, x3<x1) and an n-type impurity.

### CROSS-REFERENCE TO RELATED APPLICATION(S)

This application is based upon and claims the benefit of priority from Japanese Patent Application No. 2025-019003, filed Feb. 7, 2025, the entire contents of which are incorporated herein by reference.

### FIELD

Embodiments described herein relate generally to a semiconductor device.

### BACKGROUND

Development of a semiconductor device that reduces the on-resistance is desired.

### BRIEF DESCRIPTION OF THE DRAWINGS

FIG. 1 is a schematic cross-sectional view illustrating a semiconductor device structure according to a first embodiment.

FIG. 2 is a schematic cross-sectional view illustrating a semiconductor device structure according to a second embodiment.

FIG. 3 is a schematic cross-sectional view illustrating a semiconductor device structure according to a third embodiment.

FIG. 4 is a schematic cross-sectional view illustrating a method for manufacturing a third semiconductor region and a fourth semiconductor region according to a fourth embodiment.

FIG. 5 is a schematic cross-sectional view illustrating a method for manufacturing a third semiconductor region and a fourth semiconductor region according to a fifth embodiment.

FIG. 6 is a schematic cross-sectional view illustrating a method for manufacturing a semiconductor device according to a sixth embodiment.

FIG. 7 is a schematic cross-sectional view illustrating a method for manufacturing a semiconductor device according to a sixth embodiment.

### DETAILED DESCRIPTION

In general, according to an aspect of the invention, there is provided a semiconductor device that includes
a first electrode,
a second electrode, a direction from the first electrode toward the second electrode being along a first direction,
a third electrode between the first electrode and the second electrode in the first direction,
a first semiconductor region including Alₓ₁Ga₁₋ₓ₁N (0<x1≤1), the first semiconductor region including a first partial region, a second partial region, a third partial region, a fourth partial region, and a fifth partial region,
the first semiconductor region in which a direction from the first partial region toward the first electrode is aligned with a second direction crossing the first direction, a direction from the second partial region toward the second electrode is aligned with the second direction, a direction from the third partial region toward the third electrode is aligned with the second direction, the fourth partial region is between the first partial region and the third partial region in the first direction, and the fifth partial region is between the second partial region and the third partial in the first direction,
a second semiconductor region including Alₓ₂Ga₁₋ₓ₂N (0≤x2<1, x2<x1), in which the first partial region is between the second semiconductor region and the first electrode in the second direction, the second partial region is between the second semiconductor region and the second electrode in the second direction, the third partial region is between the third semiconductor region and the third electrode in the second direction,
a third semiconductor region including Alₓ₃Ga₁₋ₓ₃N (0≤x3<1, x3<x1), in which at least a portion of the third semiconductor region is between the first partial region and the first electrode in the second direction, the third semiconductor region includes an n-type impurity, and the first partial region does not include the n-type impurity, or a concentration of the n-type impurity in the first partial region is lower than a concentration of the n-type impurity in the third semiconductor region.

Hereinafter, embodiments of the present invention will be described with reference to the drawings. The drawings are schematic or conceptual, and the relationship between the thickness and width of each portion, the ratio of the sizes between portions, and the like are not necessarily the same as the actual ones. Even when the same portion is illustrated, the dimensions and ratios may be illustrated differently depending on the drawings. In the specification and the drawings, the same reference numerals are given to the same elements as those described above with reference to the drawings that have already been referred to, and detailed description thereof will be omitted as appropriate.

### First Embodiment

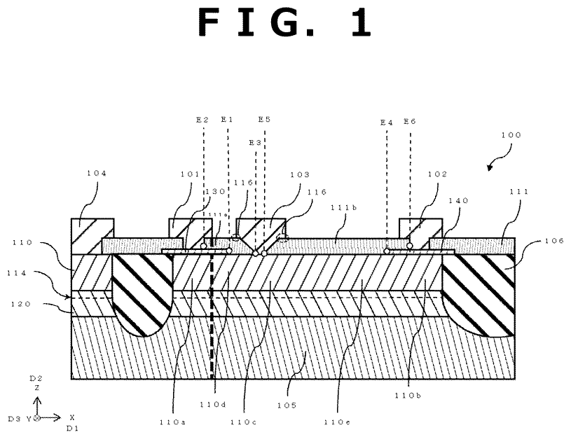

FIG. 1 is a schematic cross-sectional view illustrating a semiconductor device structure according to a first embodiment.

As shown in FIG. 1, the semiconductor device 100 according to the first embodiment includes a first electrode 101, a second electrode 102, a third electrode 103, a fourth electrode 104, a carrier region 114, a substrate 105, an element isolation region 106, a first insulating member 111, a first semiconductor region 110, a second semiconductor region 120, a third semiconductor region 130, and a fourth semiconductor region 140.

The first electrode 101 is, for example, a source electrode. The second electrode 102 is, for example, a drain electrode. The third electrode 103 is, for example, a gate electrode. The first semiconductor region 110 and the second semiconductor region 120 are nitride semiconductors having different compositions and different band gaps, and are stacked on each other. The first electrode 101, the second electrode 102, and the third electrode 103 are provided on a part of the first semiconductor region 110. The semiconductor device 100 is, for example, a high electron mobility transistor (HEMT). The third electrode 103 is in direct contact with the first semiconductor region 110. The semiconductor device according to the first embodiment is, for example, a Schottky junction field effect transistor (FET). The first electrode and the second electrode have irregularities on their surfaces (not shown).

The direction from the first electrodes 101 toward the second electrodes 102 is aligned with the first direction D1. The first direction D1 is, for example, the X-axis direction. One direction perpendicular to the X-axis direction is defined as a Z-axis direction. A direction perpendicular to the X-axis direction and the Z-axis direction is defined as a Y direction.

The third electrodes 103 are between the first electrodes 101 and the second electrodes 102 in the first direction D1.

The fourth electrode 104 is, for example, an electrode pad connected to the source electrode, and is a pad for connecting each electrode of the transistor to the outside of the transistor, or a pad used for connection to the backside of the substrate.

The first semiconducting region 110 includes Alₓ₁Ga₁₋ₓ₁N (0<x1≤1). The composition ratio of Al in the first semiconductor region 110 is, for example, not less than 0.05 and not more than 0.35. The first semiconductor region 110 includes, for example, AlGaN. The first semiconductor region 110 may be an n-type semiconductor region that is substantially undoped or contains a low concentration of n-type impurities, and the amount of n-type impurities is, for example, 2×10¹⁷ cm⁻³ or less.

The first semiconductor region 110 includes a first partial region 110a, a second partial region 110b, a third partial region 110c, a fourth partial region 110d, and a fifth partial region 110e. A second direction D2 from the first partial region 110a toward the first electrodes 101 crosses the first direction D1. The second direction D2 is, for example, the Z-axis direction.

The first electrodes 101, the second electrodes 102, and the third electrodes 103 may extend along the third direction D3. The third direction D3 intersects a plane including the first direction D1 and the second direction D2. The third direction D3 may be, for example, the Y-axis direction.

The first semiconductor region 110 spreads parallel to, for example, the X-Y plane.

The direction from the second partial region 110b toward the second electrodes 102 is aligned with the second direction D2. The direction from the third partial region 110c toward the third electrodes 103 is aligned with the second direction D2. The fourth partial region 110d is between the first partial region 110a and the third partial region 110c in the first direction D1. The fifth partial region 110e is between the third partial region 110c and the second partial region 110b in the first direction D1.

The second semiconducting region 120 includes Alₓ₂Ga₁₋ₓ₂N (0≤x2<1, x2<x1). The composition ratio of Al in the second semiconductor region 120 is, for example, not less than 0 and not more than 0.05. The second semiconductor region 120 includes, for example, GaN. The second semiconductor region 120 may be an n-type region that is substantially undoped or contains a low concentration of n-type impurities, and the amount of n-type impurities is, for example, 5×10¹⁶cm⁻³ or less.

The carrier region 114 is formed in a portion of the second semiconductor region 120 that is on the side of the first semiconductor region 110. The carrier region 114 is, for example, a two dimensional electron gas. The current flowing between the first electrode 101 and the second electrode 102 can be controlled by changing the potential of the third electrode 103. The carrier region 114 is formed by polarization generation according to a difference in lattice constant between the first semiconductor region 110 and the second semiconductor region 120.

The first insulating member 111 includes a first insulating region 111a and a second insulating region 111b. The first insulating member 111 is provided to protect the nitride semiconductor, and desirably contains, for example, SiN or SiO₂.

The first insulating region 111a is between at least a portion of the first electrodes 101 and at least a portion of the third electrodes 103 along the first direction D1. The fourth partial region 110d of the first semiconductor region 110 is between the first insulating region 111a and the second semiconductor region 120 in the second direction D2. The first insulating region 111a may be between at least a portion of the first electrodes 101 and the first partial region 110a along the second direction D2. The first insulating region 111a is between at least a portion of the third electrodes 103 and the third partial region 110c along the second direction D2.

The second insulating region 111b is between at least a portion of the second electrodes 102 and at least a portion of the third electrodes 103 along the first direction D1. The fifth partial region 110e of the first semiconductor region 110 is between the second insulating region 111b and the second semiconductor region 120 in the second direction D2. The second insulating region 111b is between at least a portion of the second electrodes 102 and the second partial region 110b along the second direction D2. The second insulating region 111b is between at least a portion of the third electrodes 103 and the third partial region 110c along the second direction D2.

The third semiconducting region 130 includes Alx₃Ga₁₋ₓ₃N (0≤x3<1, x3<x1). The third semiconductor region 130 is, for example, a GaN film containing an n-type impurity. The third semiconductor region 130 is, for example, an n⁺ GaN film. At least a portion of the third semiconducting region 130 is between the first partial region 110a of the first semiconductor region 110 and the first electrodes 101 in the second direction D2. At least a portion of the third semiconductor region 130 may be between the first insulating region 111a and the fourth partial region 110d of the first semiconductor region 110 in the second direction D2.

The third semiconductor region 130 includes an n-type impurity. On the other hand, the first partial region 110a does not include the n-type impurity, or the concentration of the n-type impurity in the first partial region 110a is lower than the n-type impurity concentration in the third semiconductor region 130. The n-type impurity contained in the third semiconductor region 130 is, for example, at least one element of Si and Ge. The n-type impurity is desirably contained at a concentration of 5×10¹⁹ cm⁻³ to 2×10²¹ cm⁻³, and particularly, in the case of using Si, it is desirably contained at a concentration of 5×10¹⁹ cm⁻³ to 5×10²⁰ cm⁻³, and in the case of using Ge, it is desirably contained at a concentration of 5×10¹⁹ cm⁻³ to 2×10²¹ cm⁻³.

The third semiconductor region 130 includes a first end E1 on the side of the fourth semiconductor region 140 in the first direction D1.

On the other hand, the first electrodes 101 include a second end E2 on the side of the substrate 105 in the second direction D2 and on the side of the third electrode 103 in the first direction D1.

The third electrodes 103 each include a third end E3 on the side of the substrate 105 in the second direction D2 and on the side of the first electrodes 101 in the first direction D1. In the first direction D1, the position of the first end E1 of the third semiconductor region 130 is positioned between the second end E2 of the first electrode 101 and the third end E3 of the third electrode 103. The first end E1 is located between the second end E2 and the third end E3 in the first direction D1. For example, the first end E1 may be disposed closer to the third electrodes 103 than a middle point between the second end E2 and the third end E3, thereby reducing the source resistance.

The third electrode 103 has a gate overlap portion 116. Here, the gate overlap portion refers to a dotted line portion of the third electrode 103 that rides on the first insulating member 111, and does not include a portion of the third electrode 103 that is in contact with the first insulating member 111 in a tapered shape. The gate overlap portions 116 are also portions of the third electrodes 103 that overlap the first insulating members 111 in the second direction D2. The upper ends of the third semiconductor regions 130 are lower than the lower ends of the gate overlap portions 116 of the third electrodes 103, and are in contact with the first electrodes 101 at the inside in the second direction D2.

At least a portion of the third semiconductor region 130 and the first electrodes 101 overlap each other in the second direction D2. At least a portion of the third semiconductor region 130 and the first electrode 101 are in direct contact with each other. The first insulating region 111a may be between the first electrodes 101 and another portion of the third semiconductor region 130 in the second direction D2.

The thickness of the third semiconductor region 130 along the second direction D2 may be less than the thickness of the first electrodes 101 along the second direction D2 and the thickness of the first insulating member 111 along the second direction D2. The thickness of the third semiconductor region 130 along the second direction D2 is preferably smaller than the thickness of the first semiconductor region 110 and the second semiconductor region 120 along the second direction D2. In particular, the thickness of the third semiconductor region 130 is preferably equal to or greater than the 5 nm and equal to or less than the 50 nm. More preferably, the thickness is equal to or less than the 20 nm. By reducing the thickness of the third semiconductor region 130, it is possible to control the shape of the third electrode 103 without affecting the process of forming the third electrode 103.

The fourth semiconductor region 140 includes Alₓ₄Ga₁₋ₓ₄N (0≤x4<1, x4<x1). The fourth semiconductor region 140 is, for example, a GaN film containing an n-type impurity. The fourth semiconductor region 140 is, for example, an n⁺GaN film. At least a portion of the fourth semiconductor region 140 is between the second partial region 110b of the first semiconductor region 110 and the second electrode 102 in the second direction D2. At least a portion of the fourth semiconductor region 140 may be between the second insulating region 111b and the fifth partial region 111e of the first semiconductor region 110 in the second direction D2.

The fourth semiconductor region 140 includes an n-type impurity similarly to the third semiconductor region 130. On the other hand, the second partial region 110b does not include the n-type impurity, or the concentration of the n-type impurity of the second partial region 110b is lower than the concentration of the fourth semiconductor region 140. Examples of the n-type impurity contained in the fourth semiconductor region 140 include Si and Ge. The n-type impurity is desirably contained at a concentration of 5×10¹⁹ cm⁻³ to 2×10²¹ cm⁻³, and particularly, in the case of using Si, it is desirably contained at a concentration of 5×10¹⁹ cm⁻³ to 5×10²⁰ cm⁻³, and in the case of using Ge, it is desirably contained at a concentration of 5×10¹⁹ cm⁻³ to 2×10²¹ cm⁻³.

The fourth semiconductor region 140 includes a fourth end E4 on the side of the third semiconductor region 130 in the first direction D1.

On the other hand, the third electrodes 103 include a fifth end E5 on the side of the substrate 105 in the second direction D2 and on the side of the second electrodes 102 in the first direction D1.

The second electrodes 102 each include a sixth end E6 on the side of the substrate 105 in the second direction D2 and on the side of the third electrodes 103 in the first direction D1. In the first direction D1, the position of the fourth end E4 of the fourth semiconductor region 140 is located between the sixth end E6 of the second electrode 102 and the fifth end E5 of the third electrode 103. The fourth end E4 is located between the fifth end E5 and the sixth end E6 in the first direction D1. For example, the fourth end E4 may be disposed closer to the second electrodes 102 than a middle point between the fifth end E5 and the sixth end E6, thereby reducing the resistance between the gate and the drain.

The upper end of the fourth semiconductor region 140 is lower than the lower end of the gate overlap portion 116, and is in contact with the second electrodes 102 at the inside in the second direction D2. This can reduce the contact resistance.

The resistivity of the third semiconductor region 130 and the fourth semiconductor region 140 is lower than the sheet resistance of the carrier region 114 at the interface between the first semiconductor region 110 and the second semiconductor region 120.

The sheet resistance of the carrier region 114 refers to the resistivity of the interface between the first semiconductor region 110 and the second semiconductor region 120 in the carrier region 114, and the value can be obtained by measuring the resistance between the first electrode 101 and the second electrode 102.

The resistivity of the third semiconductor region 130 and the fourth semiconductor region 140 is 100 Ω/□ or less, and preferably 60 Ω/□ or less. The resistivities of the third semiconductor region 130 and the fourth semiconductor region 140 can be measured as two dimensional resistivities by four terminal measurement or the like.

As shown in FIG. 1, the semiconductor device 100 may include a substrate 105. The substrate 105 may be, for example, a SiC substrate, a silicon substrate, or a GaN substrate. A buffer layer may be provided on the substrate 105 as necessary. The buffer layer includes, for example, a nitride semiconductor. For example, the second semiconductor region 120 is provided on the substrate 105 (e.g., on a buffer layer). The first semiconductor region 110 is provided on the second semiconductor region 120.

In general, in the HEMT device, in order to reduce the resistance of the device, it is attempted to reduce the distance between the gate electrode and the source electrode and the distance between the gate electrode and the drain electrode. However, since a metal is used for the electrode, unevenness is inevitably generated on the surface of the electrode due to heat treatment performed in the manufacturing process, and it is difficult to reduce the distance between the source and the gate. Therefore, it is difficult to design the first electrode 101 and the third electrode 103 to be close to each other and to reduce the resistance of the device.

In the present embodiment, the third semiconductor region 130 is provided. In contrast, there is Patent Document 1 (JP2022-187314A) in which the third semiconductor region 130 is not provided. When the present embodiment is compared with Patent Document 1, the present embodiment can reduce the resistance between the first electrode 101 and the third electrode 103 by providing the third semiconductor region 130, improve the transconductance of the semiconductor device 100, and provide a semiconductor device with low on-resistance.

Further, there is Patent Document 2 (JP2021-027165A) in which an n-type impurity region is formed across a first semiconductor region and a second semiconductor region in the vicinity of a source electrode. When the present embodiment is compared with Patent Document 2, in Patent Document 2, the two dimensional electron gas is not generated in the n-type impurity region, and the third semiconductor region 130 and the carrier region 114 in the vicinity of the source electrode are in point contact with each other, so that the contact resistance becomes unstable. In contrast, in the present embodiment, the third semiconductor region 130 and the carrier region 114 are in surface contact with each other via the first semiconductor region 110 and the second semiconductor region 120, and the flow of carriers is stable, and the on-resistance is small.

Further, by providing the fourth semiconductor region 140, the resistance between the third electrode 103 and the second electrode 102 can be further reduced, and the transconductance of the semiconductor device 100 can be improved. In addition, the fourth semiconductor region 140 and the carrier region 114 are in surface contact with each other, and thus the flow of carriers is stable, and the on-resistance is reduced.

In the case where the third semiconductor region 130 is provided, the fourth semiconductor region 140 may be omitted, but the contact resistance can be further reduced by providing both the third semiconductor region 130 and the fourth semiconductor region 140.

### Second Embodiment

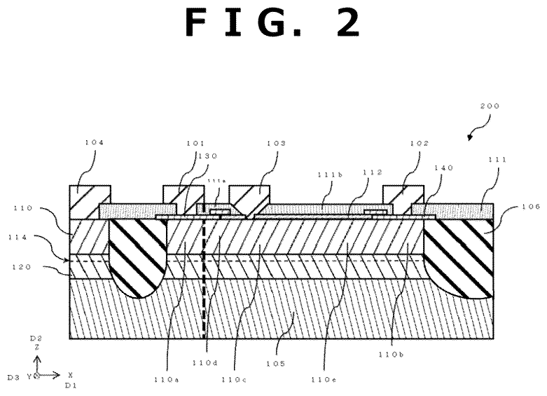

FIG. 2 is a schematic cross-sectional view illustrating a semiconductor device structure according to a second embodiment. The second embodiment is different from the first embodiment in that a second insulating member 112 is provided on a part of the first semiconductor region 110.

As shown in FIG. 2, the semiconductor device 200 according to the second embodiment includes a first electrode 101, a second electrode 102, a third electrode 103, a carrier region 114, a substrate 105, an element isolation region 106, a first insulating member 111, a second insulating member 112, a first semiconductor region 110, a second semiconductor region 120, a third semiconductor region 130, and a fourth semiconductor region 140. The third electrode 103 is in direct contact with the first semiconductor region 110. The semiconductor device according to the second embodiment is, for example, a Schottky junction field effect transistor (FET).

The second insulating member 112 is provided between the first insulating region 111 and the first semiconductor region 110 in the second direction D2. In the second direction D2, the second insulating member 112 is provided between the second insulating region 111b and the first semiconductor region 110.

The second insulating member 112 may be formed of the same material as the first insulating member 111 or a different material. For example, when the first insulating member 111 is made of SiO₂, the second insulating member 112 may be made of SiN. In the present embodiment, the second insulating member 112 is provided below the third semiconductor region 130 and the fourth semiconductor region 140, and thus the first semiconductor region 110 can be protected from damage when a portion of the third semiconductor region 130 and the fourth semiconductor region 140 is etched.

### Third Embodiment

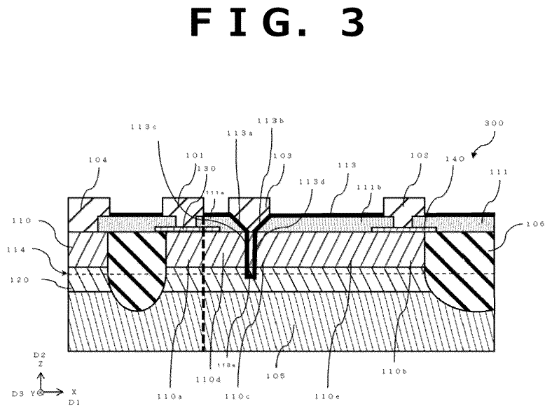

FIG. 3 is a schematic cross-sectional view illustrating the structure of a semiconductor device according to a third embodiment. The third embodiment is different from the first embodiment in that the third electrode 103 is formed inside a recess provided in the first semiconductor region 110, and a third insulating member 113 is provided between the third electrode 103 and the first insulating member 111 and between the first semiconductor region 110 and the third electrode 103. The semiconductor device 300 is, for example, an insulated gate field effect transistor (metal-oxide-semiconductor field effect transistor), and is a normally-off transistor.

As shown in FIG. 3, the semiconductor device 300 according to the third embodiment includes a first electrode 101, a second electrode 102, a third electrode 103, a carrier region 114, a substrate 105, an element isolation region 106, a first insulating member 111, a third insulating member 113, a first semiconductor region 110, a second semiconductor region 120, a third semiconductor region 130, and a fourth semiconductor region 140.

The third insulating member 113 includes a first insulating portion 113a, a second insulating portion 113b, a third insulating portion 113c, a fourth insulating portion 113d, and a fifth insulating portion 113e. The direction from the first insulating region 111a toward the first insulating portion 113a is aligned with the first direction D1. The direction from the second insulating region 111b toward the second insulating portion 113b is aligned with the first direction D1. The direction from the fourth partial region 110d toward the third insulating portion 113c is aligned with the first direction D1. The direction from the fifth partial region 110e toward the fourth insulating portion 113d is aligned with the first direction D1. The direction from the fifth insulating portion 113e toward the second semiconductor region 120 is aligned with the second direction D2.

In the semiconductor device 300, at least a portion of the third electrodes 103 is between the first insulating portion 113a and the second insulating portion 113b in the first direction D1. At least a portion of the third electrodes 103 is between the fourth partial region 110d and the fifth partial region 110e in the first direction D1. In the first direction D1, the first insulating portion 113a is between the third electrodes 103 and the first insulating region 111a. In the first direction D1, the second insulating portion 113b is between the third electrodes 103 and the second insulating region 111b. The third insulating portion 113c is between the third electrodes 103 and the fourth partial region 110d in the first direction D1. The fourth insulating portion 113d is between the third electrodes 103 and the fifth partial region 110e in the first direction D1. The fifth insulating portion 113e is between the second semiconductor region 120 and the third electrodes 103 in the second direction D2. This makes it possible to realize a normally-off transistor having a low on-resistance.

Hereinafter, in a fourth embodiment and a fifth embodiment, examples of a method of manufacturing two patterns of forming the third semiconductor region 130 and the fourth semiconductor region 140 on the first semiconductor region 110 and the second semiconductor region 120 will be described. Further, in the sixth embodiment, a method of manufacturing a semiconductor device after forming the third semiconductor region 130 and the fourth semiconductor region 140 will be described.

### Fourth Embodiment

The fourth embodiment relates to a method of forming the third semiconductor region 130 and the fourth semiconductor region 140.

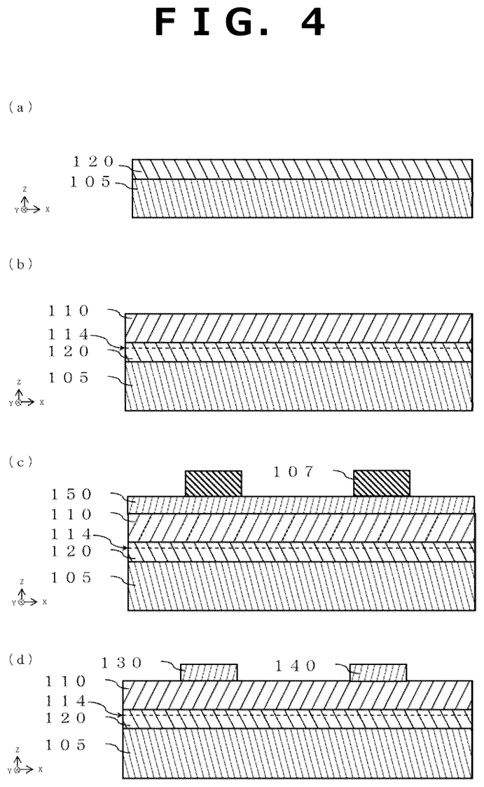

FIG. 4 is a schematic cross-sectional view illustrating a method for forming the third semiconductor region 130 according to the fourth embodiment.

First, as shown in FIG. 4(a), a stacked structure is prepared in which the second semiconductor region 120 (a GaN layer that does not substantially contain impurities) is provided on the substrate 105.

Next, as shown in FIG. 4(b), the first semiconductor region 110 (AlGaN layer substantially not containing impurities) is formed on the second semiconductor region 120 by the MOCVD method. Thus, the first semiconductor region 110 is formed on the second semiconductor region 120, and thereby, polarization occurs according to the difference in lattice constant, and the carrier region 114 is formed in a portion of the second semiconductor region 120 on the side of the first semiconductor region 110.

Next, an n⁺ GaN layer 150 to be the third semiconductor region 130 and the fourth semiconductor region 140 is formed on the first semiconductor region 110 by a sputtering method. At this time, GaN containing an n-type impurity such as Si or Ge is used as a sputtering target, or two sputtering targets containing an n-type impurity such as Si and Ge and GaN containing no impurity are used at the same time.

Further, as shown in FIG. 4(c), in order to process the shape of the n⁺ GaN layer 150, a resist layer 107 is formed on the n⁺ GaN layer 150 and the resist layer is patterned.

Further, the n⁺ GaN layer 150 is etched by RIE, then the resist layer 107 is removed. As a result, as shown in FIG. 4(d), the third semiconductor region 130 and the fourth semiconductor region 140 are formed by patterning.

### Fifth Embodiment

The fifth embodiment relates to another method of forming the third semiconductor region 130 and the fourth semiconductor region 140.

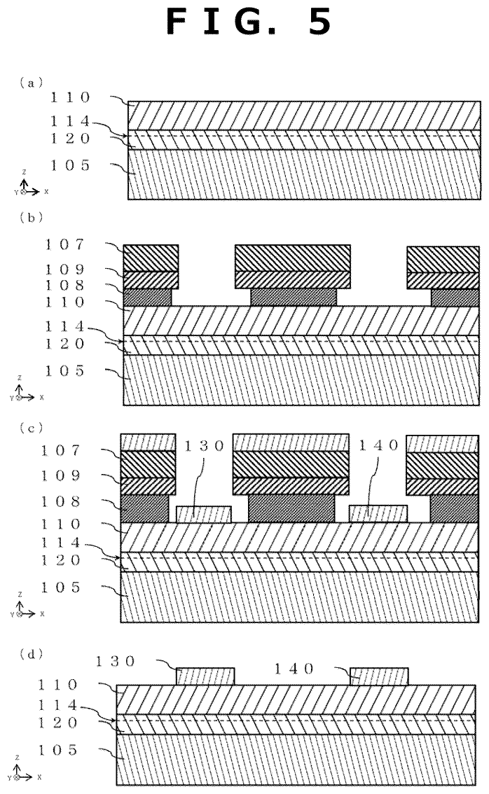

FIG. 5 is a schematic cross-sectional view illustrating a method for forming the third semiconductor region 130 and the fourth semiconductor region 140 according to the fifth embodiment.

First, a stacked structure is prepared in which the second semiconductor region 120 is provided on the substrate 105.

Next, as shown in FIG. 5(a), the first semiconductor region 110 (an AlGaN layer that does not substantially contain impurities) is formed on the second semiconductor region 120 by the MOCVD method.

Further, a SiO₂ layer 108 and a SiN layer 109 are sequentially formed thereon by using a plasma CVD method. A resist layer 107 is formed on the SiN layer 109.

Next, the resist layer 107 was patterned, and the SiO₂ layer 108 and the SiN layer 109 were opened by a combination of RIE and wet etching using the resist layer as a mask, thereby forming a stacked structure in which the first semiconductor region 110 was exposed as shown in FIG. 5(b).

Next, as shown in FIG. 5(c), an n⁺ GaN layer is deposited by using GaN containing Si or Ge as a sputtering target or using two sputtering targets of Si or Ge and GaN not containing impurities at the same time, and the third semiconductor region 130 and the fourth semiconductor region 140 are formed on the exposed first semiconductor region 110.

Lift-off was performed using an aqueous solution containing HF or a BHF-based aqueous solution (various mixed solutions in which the ratio of HF and NH₄OH was changed), the resist layer 107, the SiO₂ layer 108, and the SiN layer 109 were removed, and the third semiconductor region 130 and the fourth semiconductor region 140 (a part of the n⁺ GaN film) were left, thereby obtaining a cross-sectional structure shown in FIG. 5(d).

### Sixth Embodiment

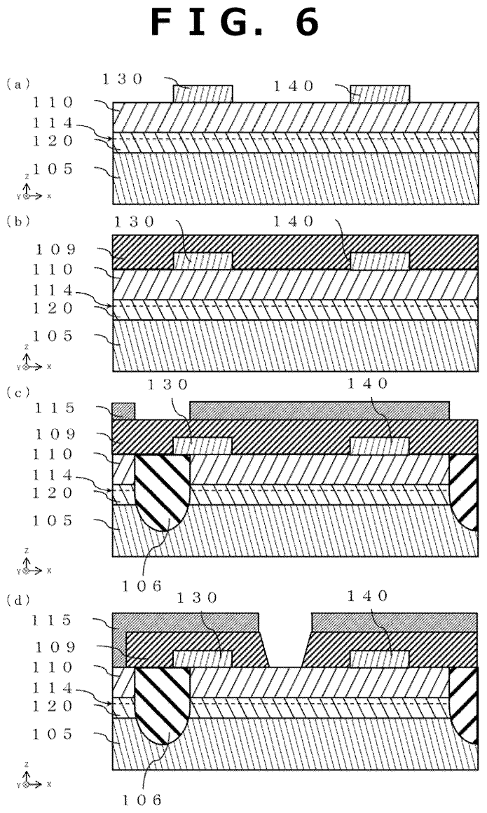

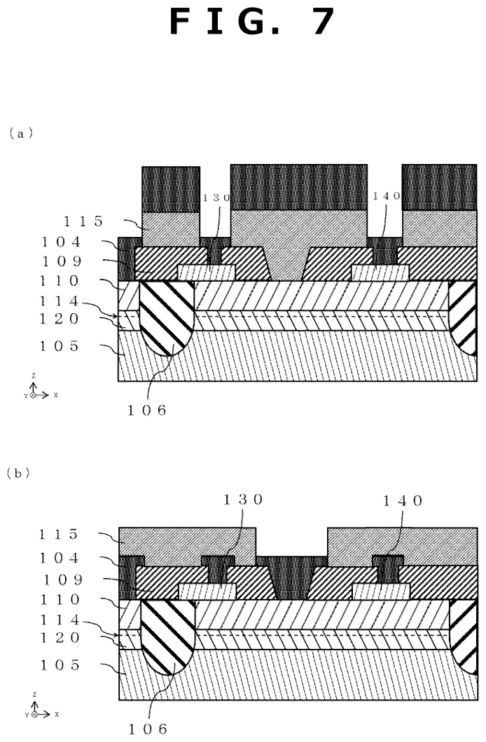

A method of manufacturing a semiconductor device using a wafer having the third semiconductor region 130 and the fourth semiconductor region 140 shown in the fourth embodiment or the fifth embodiment will be described with reference to FIG. 6 and FIG. 7.

FIG. 6(a) to 6(d), 7(a), and 7(b) are schematic cross-sectional views illustrating a method for manufacturing a semiconductor device.

As shown in FIG. 6(a), a stacked structure having the third semiconductor region 130 and the fourth semiconductor region 140, which was formed by the method shown in the fourth embodiment or the fifth embodiment, was prepared.

As shown in FIG. 6(b), a SiN layer 109 is deposited on the first semiconductor region 110 by using NH₃ gas and SiH₄ gas and a plasma CVD apparatus.

Next, a photoresist layer 115 is formed on the SiN layer 109. After the photoresist layer 115 is patterned as desired, ion implantation is performed in the opening using Ar, N, B, P, As, or the like to form an element isolation region 106, thereby obtaining a structure having a cross section shown in FIG. 6(c). Thereafter, the photoresist layer 115 is removed.

Further, a photoresist layer 115 is formed on the SiN layer 109, and after the photoresist layer 115 is patterned as desired by photolithography, the SiN layer 109 of the gate portion is etched by an RIE apparatus using a fluorine-based gas (F-based gas), thereby obtaining a cross-sectional structure shown in FIG. 6(d).

Thereafter, the photoresist layer 115 is removed. A photoresist layer 115 is again formed on the SiN layer 109, and the photoresist layer 115 is patterned. Openings are formed in the SiN layer 109 at positions where the first electrode 101 and the second electrode 102 are formed, and etching is performed until the surface of the n⁺ GaN layer is exposed, using a fluorine-based RIE apparatus. A photoresist layer 115 is formed again for lift-off, and patterning is performed so that an opening is slightly wider than the opening of the SiN layer 109. Next, the first electrode 101 and the second electrode 102, which are metal ohmic electrodes containing Ti and Al, were formed using a vapor deposition apparatus, and the cross-sectional structure shown in FIG. 7(a) was obtained. Thereafter, the unnecessary metal portion is lifted off together with the photoresist layer 115.

Further, as shown in FIG. 7(b), a photoresist layer 115 is formed again, an opening is formed in a position of the photoresist layer 115 where the third electrode 103 is to be formed, and then a metal electrode containing, for example, Ni and Au is formed in the opening using a vapor deposition apparatus to form the third electrode 103.

Thereafter, the unnecessary metal portion and the photoresist were removed to obtain a semiconductor device.

Information on the thickness and shape of the semiconductor region in the semiconductor device is obtained by, for example, electron microscope observation. The information on the composition is obtained by secondary ion mass spectrometry (SIMS), energy dispersive X-ray spectroscopy (EDX), or the like.

In the specification of the present application, “perpendicular” and “parallel” include not only strictly perpendicular and strictly parallel but also, for example, variations in the manufacturing process, and may be substantially perpendicular and substantially parallel.

The embodiments of the present invention have been described above with reference to specific examples. However, the present invention is not limited to these specific examples. For example, one skilled in the art may similarly practice the invention by appropriately selecting specific configurations of components included in the nitride semiconductor such as the nitride region and the substrate from known art; and such practice is within the scope of the invention to the extent that similar effects can be obtained.

In addition, combinations of any two or more elements of the specific examples within a technically possible range are also included in the scope of the present invention as long as the gist of the present invention is included.

Moreover, all nitride semiconductors and semiconductor devices practicable by an appropriate design modification by one skilled in the art based on the nitride semiconductors and the semiconductor devices described above as embodiments of the invention also are within the scope of the invention to the extent that the purport of the invention is included.

In addition, within the scope of the idea of the present invention, those skilled in the art can conceive various changes and modifications, and it is understood that those changes and modifications also belong to the scope of the present invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. These embodiments and modifications thereof are included in the scope and gist of the invention, and are included in the invention described in the claims and the equivalent scope thereof.

What is claimed is:

1. A semiconductor device comprising,
a first electrode,
a second electrode, a direction from the first electrode toward the second electrode being along a first direction,
a third electrode between the first electrode and the second electrode in the first direction,
a first semiconductor region including Alₓ₁Ga₁₋ₓ₁N (0<x1≤1), the first semiconductor region including a first partial region, a second partial region, a third partial region, a fourth partial region, and a fifth partial region,
the first semiconductor region in which a direction from the first partial region toward the first electrode is aligned with a second direction crossing the first direction, a direction from the second partial region toward the second electrode is aligned with the second direction, a direction from the third partial region toward the third electrode is aligned with the second direction, the fourth partial region is between the first partial region and the third partial region in the first direction, and the fifth partial region is between the second partial region and the third partial in the first direction,
a second semiconductor region including Alₓ₂Ga₁₋ₓ₂N (0≤x2<1, x2<x1), in which the first partial region is between the second semiconductor region and the first electrode in the second direction, the second partial region is between the second semiconductor region and the second electrode in the second direction, the third partial region is between the third semiconductor region and the third electrode in the second direction,
a third semiconductor region including Alₓ₃Ga₁₋ₓ₃N (0≤x3<1, x3<x1), in which at least a portion of the third semiconductor region is between the first partial region and the first electrode in the second direction, the third semiconductor region includes an n-type impurity, and the first partial region does not include the n-type impurity, or a concentration of the n-type impurity in the first partial region is lower than a concentration of the n-type impurity in the third semiconductor region.

2. The semiconductor device according to claim 1, further comprising
a first insulating member which includes a first insulating region and a second insulating region, the first insulating region being between the first electrode and the third electrode in the first direction, the second insulating region being between the second electrode and the third electrode in the first direction,
wherein the fourth partial region is between the first insulating region and the second semiconductor region in the second direction, the fifth partial region is between the second insulating region and the second semiconductor region in the second direction, the third semiconductor region extends to between the fourth partial region and the first insulating region in the first direction.

3. The semiconductor device according to claim 2, wherein
the third semiconductor region does not overlap the third electrode in the second direction.

4. The semiconductor device according to claim 1, wherein
a first end portion of the third semiconductor region being an end portion on the side of the third electrode in the first direction is positioned on the side of the third end portion of a midpoint between a second end portion of the first insulating region being an end portion on the side of the first electrode in the first direction and a third end portion of the first insulating region being an end portion on the side of the third electrode in the first direction.

5. The semiconductor device according to claim 2, wherein
a thickness in the second direction of the third semiconductor region is thinner than a thickness in the second direction of the first electrode and thinner than a thickness of the first insulating member.

6. The semiconductor device according to claim 5, wherein
a thickness in the second direction of the third conductive region is not more than a 50 nm.

7. The semiconductor device according to claim 1, wherein
a fourth semiconductor region is provided under the second electrode, and
a fourth end portion of the fourth semiconductor region being an end portion on the side of the third electrode in the first direction is positioned on the side of the sixth end portion of a midpoint between a fifth end portion of the second insulating region being an end portion on the third electrode side in the first direction and a sixth end portion of the second insulating region being on the side of the second electrode in the first direction.

8. The semiconductor device according to claim 1, wherein
the first electrode and the second electrode have an uneven surface.

9. The semiconductor device according to claim 1, wherein
a resistivity of the third semiconductor region and the fourth semiconductor region is lower than a sheet resistivity of a carrier region at an interface between the first semiconductor region and the second semiconductor region, and is 100 Ω/□ or less.

10. The semiconductor device according to claim 7, wherein
a resistivity of the third semiconductor region and the fourth semiconductor region is lower than a sheet resistivity of a carrier region at an interface between the first semiconductor region and the second semiconductor region, and is 100 Ω/□ or less.

11. The semiconductor device according to claim 1, wherein
the third semiconductor region and the fourth semiconductor region are n⁺ GaN films.

12. The semiconductor device according to claim 7, wherein
the third semiconductor region and the fourth semiconductor region are n⁺ GaN films.

13. The semiconductor device according to claim 2, further comprising,
a second insulating member between the first semiconductor region and the first insulating member in the second direction.

14. The semiconductor device according to claim 2, wherein
the third electrode includes a recess, and
a third insulating member is on the first insulating member and along the recess.
